(19) United States
(12) Patent Application Publication
(10) Pub. No.: US 2025/0201538 A1
(43) Pub. Date: Jun. 19, 2025

(54) ESC DESIGN WITH ENHANCED TUNABILITY FOR WAFER FAR EDGE PLASMA PROFILE CONTROL

(71) Applicant: Applied Materials, Inc., Santa Clara, CA (US)

(72) Inventors: Jian LI, Fremont, CA (US); Edward P. HAMMOND, IV, Hillsborough, CA (US); Juan C. ROCHA, San Carlos, CA (US); Thomas NOWAK, Cupertino, CA (US)

(21) Appl. No.: 18/543,302

(22) Filed: Dec. 18, 2023

(51) Int. Cl. H01J 37/32; H01L 21/683

(52) U.S. Cl. CPC H01J 37/32724; H01J 37/32807; H01L 21/6833

(57) ABSTRACT

A substrate support for use in a substrate processing chamber includes a ceramic electrostatic chuck having a body having an outer diameter, a first side configured to support a substrate and a second side opposite the first side, and a thickness between the first side and the second side, wherein the body comprises at least one chucking electrode having a radially outer surface and a far edge electrode disposed adjacent to the chucking electrode and extending radially outwardly of the at least one chucking electrode.

### BACKGROUND

### Field

Examples of the present disclosure generally relate to apparatus and methods for fabricating semiconductor devices. More specifically, apparatus disclosed herein relate to an electrostatic chuck assembly for use in a plasma processing chamber.

### Background of the Related Art

The fabrication of microelectronic devices typically involves a complicated process sequence requiring hundreds of individual processes performed on semi-conductive, dielectric, and conductive substrates. Examples of these processes include oxidation, diffusion, ion implantation, thin film deposition, cleaning, etching, and lithography, among other operations. Each operation is time consuming and expensive.

With ever-decreasing critical dimensions for microelectronic devices, the design and fabrication for these devices on substrates is becoming or has become increasingly complex. Control of the critical dimensions and process uniformity becomes increasingly more significant. Complex multilayer stacks used to make microelectronic devices involve precise process monitoring of the critical dimensions for the thickness, roughness, stress, density, and potential defects. Process recipes for forming the devices have multiple incremental processes to ensure critical dimensions are maintained. Typically, each incremental process may utilize one or more processing chambers that adds additional time for forming the devices and also increases opportunities for forming defects.

As critical dimensions on these devices shrink, past fabrication techniques encounter new hurdles. For example, one operation used in the fabrication is a metal bottom up trench fill in the formation of these devices. As the smaller critical dimensions for these devices shrink, the fill material tends to close off the top of the trench prior to completely filling at the bottom. Additionally, process skew may occur due to non-uniform plasma coupling to an electrostatic chuck, supporting a substrate during device formation, and/or non-uniformity of the temperature across the electrostatic chuck, negatively impacting process performance. For example, at the circumferential edge region of a substrate supported on an electrostatic chuck, the interaction between the substrate and the plasma may be different that that occurring in the more central area of the substrate, leading to an annular outer substrate region where inconsistent manufacture of “good” devices occurs.

Therefore, there is a need for an improved processing system in which control of the interaction of the plasma with the substrate in the circumferential outer region of the substrate can be better controlled.

### SUMMARY

Examples of a substrate support are provided herein. In one aspect, the substrate support includes a ceramic electrostatic chuck having a body, the body having an outer diameter, a first side configured to support a substrate and a second side opposite the first side, and a thickness between the first side and the second side, wherein the body comprises, at least one chucking electrode having a radially outer surface, a far edge electrode disposed adjacent to the chucking electrode and extending radially outwardly of the at least one chucking electrode, wherein the far edge electrode has a thickness in the thickness direction of the body which is greater than the thickness of the at least one chucking electrode in the thickness direction of the body.

In another example, the substrate support includes a ceramic body having a first surface, at least one heater, at least one chucking electrode having an outer circumferential surface, and a first annular member having a first inner circumferential surface and a first outer circumferential portion, a portion of the outer circumferential surface of the chucking electrode extending between the first surface of the ceramic body and the first inner circumferential portion of the first annular member.

In another aspect, a method of manufacturing a substrate support includes providing a ceramic body having a first surface configured to receive a substrate thereon, providing an annular ring having a first surface facing side and a first thickness in the ceramic body, providing a chucking electrode having a first surface facing side and a second thickness different than the first thickness in the ceramic body, and positioning the annular ring circumferentially around the chucking electrode.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 depicts a schematic side view of a process chamber having a substrate support in accordance with at least some examples of the present disclosure.

FIG. 2A depicts a schematic partial side view of the substrate support in accordance with one example of the present disclosure.

FIG. 2B depicts a blow up of a portion of the substrate support shown in FIG. 2A.

FIG. 3A depicts a schematic partial side view of the substrate support in accordance with one example of the present disclosure.

FIG. 3B depicts a blow up of a portion of the substrate support shown in FIG. 3A.

FIG. 4A depicts a schematic partial side view of the substrate support in accordance with one example of the present disclosure.

FIG. 4B depicts a blow up of a portion of the substrate support shown in FIG. 4A.

FIG. 4C depicts an exploded view of the electrodes within the substrate support shown in FIG. 4B.

FIG. 5A depicts a schematic partial side view of the substrate support in accordance with one example of the present disclosure.

FIG. 5B depicts a blow up of a portion of the substrate support shown in FIG. 5A.

FIG. 5C depicts an exploded view of the electrodes with in the substrate support shown in FIG. 5B.

FIG. 6A depicts a detailed view of the unitary spoke mesh.

FIG. 6B depicts a view of the sheet of conductive wire mesh.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the present disclosure, an electrostatic chuck assembly is provided which has an edge ring resting on a ceramic plate. The ceramic plate supports a substrate during plasma processing. The ceramic plate has one or more heaters therein that can heat the substrate up to, for example, 700 degrees C. The ceramic plate has here a pair of chucking electrodes for chucking the substrate. An edge electrode is extended to nearly the very edge of the ceramic plate, and can be powered by an alternating current (AC) power supply for tuning the plasma adjacent the edge of the substrate. This includes, for example, to create a plasma sheath at the substrate edge more similar to that over more central regions of the substrate, hence reducing non-uniform processing adjacent to the substrate edge compared to the rest of the substrate. As a result the available real estate on the substrate for productive manufacture of a semiconductor devices can be increased. By better control of the plasma at the circumferential outer region of the substrate, control of the film profile across the full surface of the substrate can be maintained while operating at frequencies from 350 kHz to 60 MHz. The ceramic plate enables AC, such as RF, pulsing therein at very low duty cycles with a pulsing frequency between 0.2 Hz to 20 Hz to prevent film damage by enabling bottom-up trench fill. The low duty cycle AC pulsing at the 0.2 Hz to 20 Hz level, can be utilized for plasma enhanced chemical vapor deposition (PECVD) and plasma enhanced atomic layer deposition (PEALD) processes which enable bottom-up filling of trenches by preventing the sidewalls of the trenches from closing in during the fill, which deters porous film formation in the trenches.

An embedded ground electrode helps to prevent AC coupling to the chamber bottom, thereby reducing required chamber depth, and thus, the chamber volume. The reduced chamber volume beneficially reduces the purge time required during a PEALD process.

Advantageously, the high temperature electrostatic chuck assembly can perform both PECVD/PEALD deposition as well as in-situ etch/treatment processes all while using the same ceramic plate. The electrostatic chuck assembly enables improved film coverage at the outer circumferential portion of the substrate by using the edge electrode. The electrostatic chuck assembly additionally has a reduced footprint due to an embedded ground electrode that also makes the electrostatic chuck assembly more reliable by avoiding plasma light up in the gaps between the chamber components in vacuum as seen in previous approaches to grounding.

Herein, the electrostatic chuck is configured to include one or more substrate chucking electrodes which can also be used, by superimposing an alternating current, such as RF, thereon, to cause the electrostatic chuck to establish a self-bias thereon and thereby cause ions, in a plasma to which a substrate chucked thereon is exposed, to bombard the surface of the substrate and features formed thereon or thereinto. Additionally, a separate bias electrode, here called an active edge electrode, surrounds the chucking electrode(s) and is spaced therefrom, and can be biased independently of the alternating current such as RF bias on the chucking electrodes to control the self bias on the electrostatic chuck, and thus the plasma intensity and plasma ion bombardment of the substrate adjacent the edge thereof. Here, several configurations of an active far edge electrode are provided, including in one aspect an active far edge electrode having a different thickness than that of the chucking electrode(s). This thicker active far edge electrode can be directly coupled to a power supply to provide an alternating current power thereto, by one or more configuration of wiring in the body of the electrostatic chuck. In another configuration, the active far edge electrode is not directly connected to a power supply, and is instead biased by being capacitively coupled to another powered element in the electrostatic chuck to provide electrical energy thereto. Additionally, an active far edge electrode having the same thickness as the chucking electrodes, and being capacitively coupled to another element in the electrostatic chuck, is also provided herein.

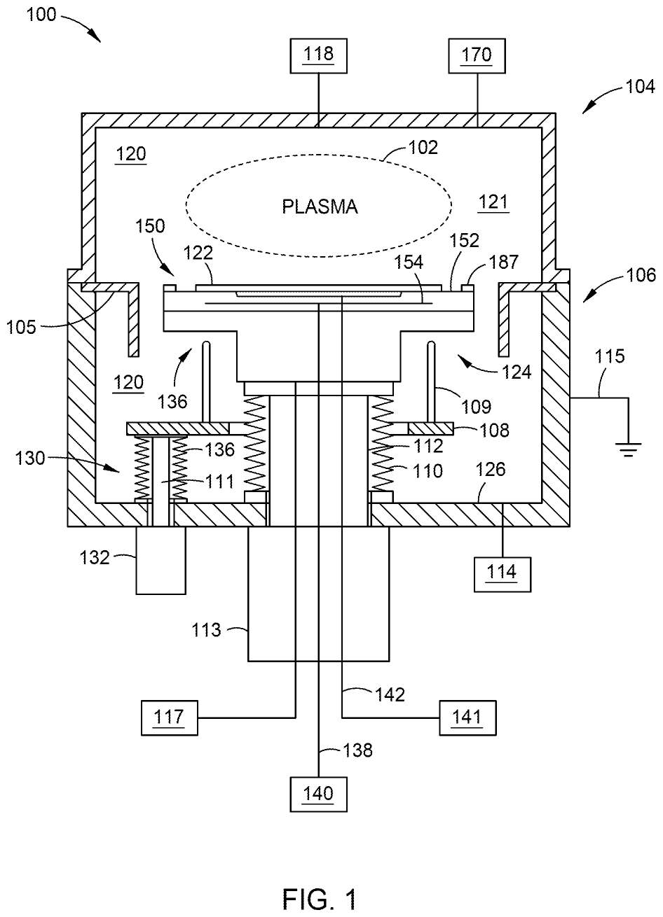

FIG. 1 depicts a schematic side view of a plasma processing chamber 100 having a substrate support 124 configured as an electrostatic chuck 152 in accordance with at least some examples of the present disclosure. In some examples, the plasma processing chamber 100 is a reactive ion etch processing chamber. However, other types of processing chambers configured for different processes can also use or be modified for use with examples of the substrate support 124 described herein.

The plasma processing chamber 100 is configured as a vacuum chamber that is suitably adapted to maintain sub-atmospheric pressures within a chamber interior volume 120 during substrate processing operations therein. The plasma processing chamber 100 includes a chamber body 106 covered by a lid 104 which together enclose a processing volume 121 located in the upper portion of the chamber interior volume 120 between the substrate support 124 and the lid 104. The plasma processing chamber 100 may also include one or more shields or liners 105 circumscribing various chamber components to prevent unwanted reaction between such components and process materials used in the processing of the substrate, or byproducts of their reaction with the substrate. The chamber body 106 and lid 104 may be made of metal, such as aluminum. The chamber body 106 may be electrically grounded via a coupling to ground 115.

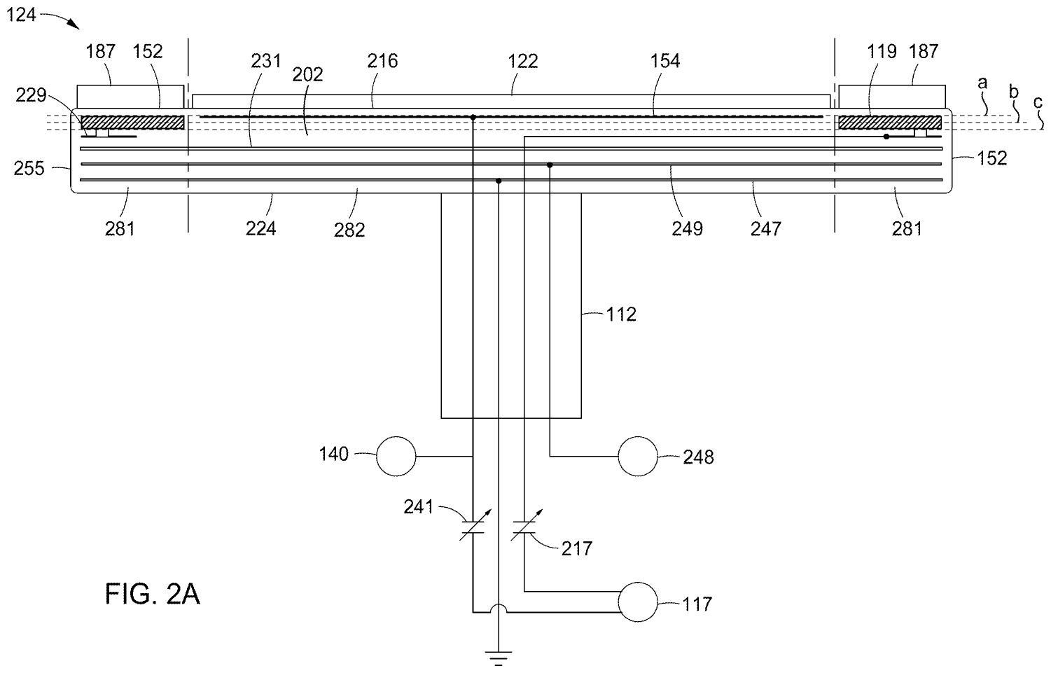

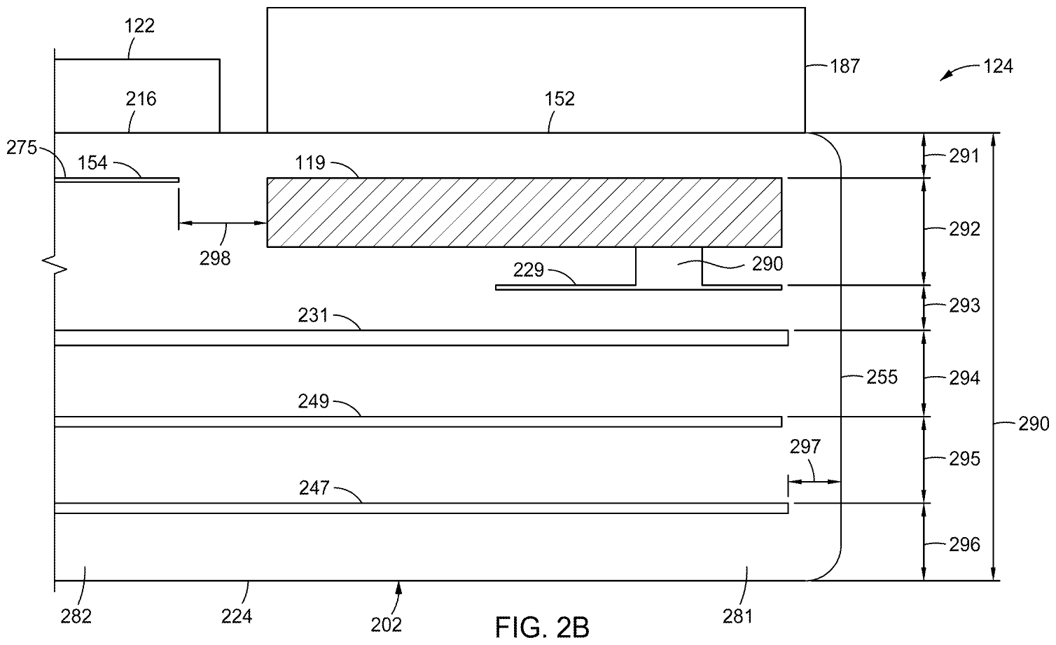

The substrate support 124 is disposed within the chamber interior volume 120 to support and retain a substrate 122 thereon, such as a semiconductor wafer. The substrate support 124 may generally comprise an electrostatic chuck assembly 150 (described in more detail below with respect to FIG. 2B) and a hollow support shaft 112 for supporting the electrostatic chuck assembly 150. The electrostatic chuck assembly 150 comprises an electrostatic chuck 152 having one or more chucking electrodes 154 disposed therein, the chucking electrodes having a substrate facing surface 275 and a substrate opposed surface 276. The substrate facing surface 275 extends along plane a within and generally parallel to the substrate receiving surface of the electrostatic chuck 152 and the substrate opposed surface 276 extends along plane b generally parallel to plane a. An edge ring 187 is disposed on the substrate support 124 and circumscribes a substrate 122 when a substrate is supported on the substrate support 124. The electrostatic chuck 152 electrostatically chucks the substrate 122 to the substrate support 124.

The hollow support shaft 112 provides a conduit to provide, for example, backside gases, process gases, fluids, coolants, power, or the like, to the substrate support 124. In some examples, the hollow support shaft 120 is attached to a bottom surface of the plasma chamber body 106 and the substrate support 124 is fixed in the processing chamber 100. In other examples, the hollow support shaft 112 is coupled to a lift mechanism 113, such as an actuator or motor, which provides vertical movement of the electrostatic chuck assembly 150 between an upper, processing position (as shown in FIG. 1) and a lower, transfer position (not shown). A bellows assembly 110 is disposed about the hollow support shaft 112 and is coupled between the electrostatic chuck assembly 150 and a bottom surface 126 of plasma processing chamber 100 to provide a flexible seal that allows vertical motion of the electrostatic chuck assembly 150 while preventing loss of vacuum from within the plasma processing chamber 100.

The hollow support shaft 112 provides a conduit for coupling a backside gas supply 141, a negative pulsed DC power source 140, and a bias power supply 117 to the electrostatic chuck assembly 150. In some examples, the bias power supply 117 includes one or more RF bias power sources. The backside gas supply 141 is disposed outside of the chamber body 106 and supplies heat transfer gas to the electrostatic chuck assembly 150 and therethrough to the interface region between the electrostatic chuck 152 and a substrate 122 chucked thereto. In some examples, the substrate support 124 may alternatively include AC, DC, or RF bias power.

The substrate support 124 may, or may not, include a substrate lift assembly 130. The substrate lift assembly 130 may include lift pins 109 mounted on a platform 108 connected to a shaft 111 that is coupled to a second lift mechanism 132 for raising and lowering the platform 108 and pins 109 so that the substrate 122 may be placed on or removed from the electrostatic chuck assembly 150. The electrostatic chuck assembly 150 includes through holes to receive the lift pins 109. A bellows assembly 131 is coupled between the substrate lift assembly 130 and the bottom surface 126 to provide a flexible seal that maintains the chamber vacuum during vertical motion of the substrate lift 130. Alternately, the substrate lift assembly 130 may be included entirely inside the processing chamber 100, for example within the substrate support assembly 124.

In some examples, the electrostatic chuck assembly 150 includes gas distribution channels 142 extending from a lower surface of the electrostatic chuck assembly 150 to various openings in an upper surface of the electrostatic chuck assembly 150. The gas distribution channels 142 are configured to provide backside gas, such as nitrogen (N) or helium (He), to the top surface of the electrostatic chuck assembly 150 to act as a heat transfer medium. The gas distribution channels are in fluid communication with the backside gas supply 141 via a conduit 142 to control the temperature and/or temperature profile of the electrostatic chuck assembly 150 during use.

The plasma processing chamber 100 is coupled to and in fluid communication with a pumping system 114 that includes a throttle valve (not shown) and vacuum pump (not shown) which are used to exhaust the plasma processing chamber 100. The pressure inside the plasma processing chamber 100 may be regulated by adjusting the throttle valve and/or vacuum pump. The plasma processing chamber 100 is also coupled to and in fluid communication with a process gas supply 118 that may supply one or more process gases to the plasma processing chamber 100 for processing the substrate 122 disposed therein.

In operation, a plasma 102 is created in the chamber interior volume 120 to perform one or more processes. The plasma 102 may be created by coupling power from a plasma power source (e.g., RF plasma power supply 170) to a process gas via one or more electrodes near or within the chamber interior volume 120 to ignite the process gas and create the plasma 102. A bias power may also be provided from the bias power supply 117 to the one or more chucking electrodes 154 within the electrostatic chuck assembly 150 to attract ions from the plasma 102 towards the substrate 122. The RF plasma power supply 170 may provide RF energy at a frequency of about 40 MHz or greater to the processing chamber 100 for maintaining the plasma 102 therein.

FIG. 2A depicts a schematic partial side view of the substrate support 124 in accordance with at least one example of the present disclosure. FIG. 2B depicts an enlarged view of a portion of the substrate support shown in FIG. 2A and will be relied on for providing a detailed view for the discussion of feature locations.

The electrostatic chuck 152 has a body 202. The body 202 may be uniformly formed of a ceramic material. In one example, the body 202 is made of AlN, Al2O3, quartz, or other suitable material with electrodes and connections therefor embedded therein. The body 202 of the electrostatic chuck 152 is fabricated using a ceramic preform such as a compressed ceramic powder or a mold form containing the powder with electrodes embedded therein. This preform is then fired to a temperature sufficient to form the final continuous ceramic plate with the electrodes and any electrical connections therefor embedded therein.

The body 202 includes a first side 216 configured to support the substrate 122 and a second side 224 opposite the first side 216. The electrostatic chuck 152 has an outer circumferential surface 255 having an outer diameter. The body 202 has an inner portion 282 and an outer portion 281 extending from the inner portion to the outer diameter of the outer circumferential surface 255, the outer portion 281 surrounding the inner portion 282. The substrate 122 is disposable on the inner portion 282 and the edge ring 187 is disposed on the outer portion 281. Alternatively, the edge ring is formed integrally with the body and does not need to be a separate element. In this case, the integral edge ring surrounds the inner portion 282 and thus a substrate when supported thereon. The body 202 thickness between the first side 216 and the second side 224 is between about 18 mm and 22 mm, such as about 20 mm.

The body 202 of the electrostatic chuck 152 includes therein one or more chucking electrodes 154, floating mesh 231, optionally a spoke mesh 229, one or more heaters 249, and, optionally, a ground mesh 247. The one or more chucking electrodes 154 and the spoke mesh 229 may be all be coupled to one or more alternating current (AC) sources, such as RF power sources. The floating mesh 231 may optionally be coupled to one or more alternating current (AC) sources, such as RF power sources. The one or more chucking electrodes 154 are coupled to a DC power supply and may additionally be optionally coupled to the (AC) or RF power source. Where the chucking electrodes 154 are coupled to an AC, such as RF, power source, they additionally function to cause a negative self bias to form on the electrostatic chuck. The magnitude of the self bias effects the thickness of the sheath between plasma and the electrostatic chuck 152, and thus the quantity and energy of plasma ions being attracted to the substrate 122 on the electrostatic chuck 152. This in turn effects the quantity of physical removal or redistribution of material on the substrate caused by the plasma ion bombardment.

The one or more chucking electrodes 154 are embedded in the inner portion 282 of the body 202 immediately adjacent to the first side 216. The chucking electrodes 154, when energized, electrostatically chuck the substrate 122 to the first side 216 of the electrostatic chuck 152. The one or more chucking electrodes 154 may be configured to create a monopolar or bipolar chucking structure. In some examples, the electrostatic chuck 152 provides Coulombic chucking. In some examples, the electrostatic chuck 152 provides Johnsen-Rahbek chucking. In some examples, the one or more chucking electrodes 154 comprise an upper electrode, a lower electrode (not shown), and a plurality of posts electrically coupled to the upper and lower electrodes. In one or more examples, the chucking electrode may additionally be a RF bias electrode. For example, RF power may be supplied on top of the DC chucking

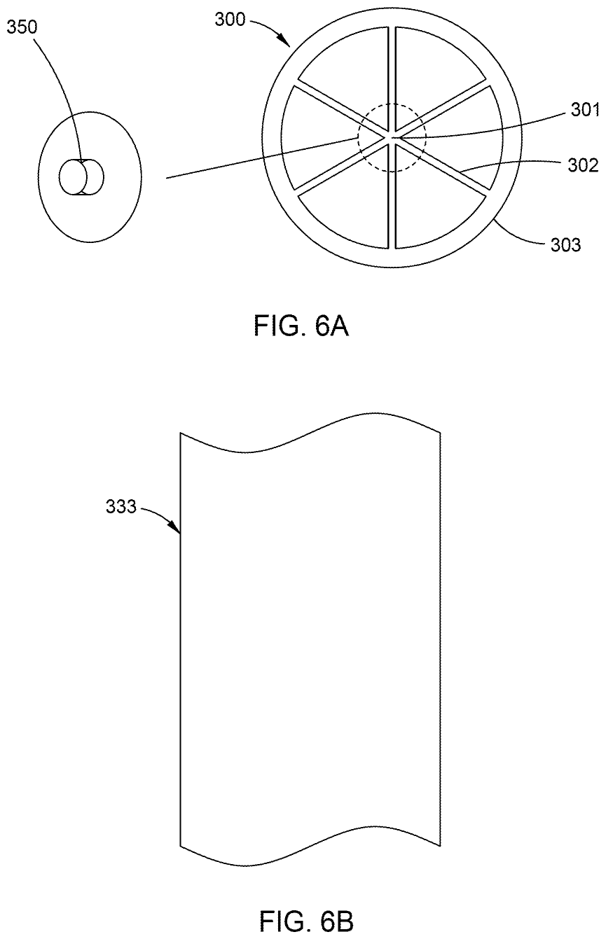

Adjacent to the chucking electrodes 154 are one or more active far edge electrodes 119 disposed within the outer portion 281 of the body 202. Here, the active far edge electrode 119 has a thickness greater than that of the chucking electrodes 154, for example 2 to 10, or 2 to 5 times, greater than that of the chucking electrodes 154. Here, the substrate facing surface of the far edge electrode 119 extends from the same plane, plane a of FIG. 2A, as the substrate facing surface 275 of the chucking electrodes 154, to a second plane, plane c, inwardly of the body 202 of the electrostatic chuck 152 beyond the plane b of the substrate opposed surface 276 of the chucking electrodes 154. The active far edge electrode 119 may be configured from a woven unitary mat or unitary mesh sheet 333 (FIG. 6B) of individual molybdenum wires, each wire having a thickness or diameter on the order of 0.05 to 1.0 mm or greater. The mesh pattern of the individual wires in the unitary mesh sheet 333 comprise for example, a cross pattern, where one plurality of the wires runs in a first direction and the second plurality of the wires runs in a second direction generally orthogonal to the first direction, and each wire extending in the first direction alternatingly crosses below a wire, then over the next wire, below the next wire, etc. of the second plurality of wires. Three sets of wires may also be employed, each of the wires in each set of the wires extending generally parallel to one another and oriented with their lengths in one of a first, second and third direction, where each of the first second and third directions are offset from one another by about 60 degrees. The thickness of each wire can also be larger than 1.0 mm to create a thicker mesh. Here, the active far edge elctrode 119 is configured of a plurality of annular rings, each cut or stamped out of a unitary mesh sheet, and stacked one on top of the other in the ceramic powder preform to provide a desired thickness of the active far edge electrode 119 in the direction between plane a and plane c of the electrostatic chuck 152.

Alternatively, the active far edge electrode may be compose of nickel molybdenum powder that has been molded into preform and then fired as part of the firing of the ceramic of the electrostatic chuck to provide a thick active far edge electrode. The active far edge electrode 119 may be coupled to the bias power supply 117 for biasing and shaping the plasma sheath over the portion of the electrostatic chuck adjacent to which they are embedded. The active far edge electrode 119 is configured to operate independently of the chucking electrodes 154. However, the chucking electrodes 154 may optionally be coupled to the bias power supply 117 for shaping the plasma sheath in addition to the chucking power supply. A variable capacitor 241 may be disposed between the bias power supply 117 and the chucking electrodes 154 for isolating the chucking electrodes 154 from the active far edge electrodes 119. In one example, the active far edge electrodes 119 may be energized while the chucking electrodes 154 are de-energized. However, it should be appreciated that the chucking electrodes 154 may be energized at the same time the active far edge electrodes 119 is energized or alternately while the active far edge electrode 119 is de-energized. In another example, capacitors 241 and 217 can also be varied to redistribute RF power from source 117 between electrodes 154 and 119, to control the plasma shape above the edge of substrate 122.

In some examples, an AC energy supplied by the bias power supply 117 may have a frequency of between about 350 KHz to about 60 MHz. In one example, the bias power supply 117 is configured to generate the AC signal overlaid on a pulsed or non pulsed voltage signal of the negative pulsed DC power source 140. In one example, the voltage waveform of the negative pulsed DC power source 140 may include a pulsed voltage signal range of about at 0.2 Hz to about 20 Hz with a duty cycle ranging from 10% to 100% overlaid with the AC signal of about 350 KHz to about 60 Mhz. The negative pulsed DC power source 140 is configured to provide a power profile to correct plasma sheath bending and maintain a substantially flat plasma sheath profile across the substrate 122.

The edge ring 187 is horizontally disposed above the active far edge electrode 119 in the outer portion 281 of the electrostatic chuck 152. The active far edge electrode 119 may be additionally coupled to a negative pulsed DC power supply (not shown) to chuck the edge ring 187 to the electrostatic chuck 152. The negative pulsed DC power supply is configured to provide a power profile to correct plasma sheath distortion and maintain a substantially uniform plasma sheath profile along the edge of the substrate 122.

All dimensions discussed further below are taken along the outer diameter of the outer circumferential surface 255. For example, the body 202 has a pocket disposed in the center of the first side 216 of the body 202. The pocket is above and extends beyond the length of the chucking electrodes 154. The pocket may extend into the body between about 0.5 mm to about 1.3 mm such as 1 mm. When describing the distance the chucking electrodes 154 are disposed below the first side 216, the distance includes the material of the body 202 not present in the pocket. Thus, when the chucking electrodes 154 are described as disposed 2 mm below the first side 216, the chucking electrodes 154 may be only 1 mm below the surface of the pocket.

The active far edge electrode 119 may be spaced a distance of about 2 mm to about 3 mm from the outer circumferential surface 255. For example, the distance from the active far edge electrode 119 may be about 2.5 mm from the outer circumferential surface 255 of the electrostatic chuck 152. The chucking electrodes 154 may be spaced radially a distance of about 2 mm to about 6 mm, such as about 4 mm from the radially inner surface of the active far edge electrode 119 adjacent thereto. The chucking electrodes 154 and the active far edge electrode 119 may be a distance 291 of about 1.5 mm to about 3 mm, such as about 2.3 mm, below the first side 216 of the electrostatic chuck 152. The active far edge electrode 119 is extended to nearly the very edge of the body 202 so that a more uniform thickness extension of the plasma sheath from the central region of the substrate to a location radially outwardly of the edge of the substrate is obtained about the circumference of the substrate 122, which reduces process differences between the central and edge regions of the substrate 122, and thus in turn increases the effective real estate of the substrate on which devices can be successfully manufactured or formed.

The spoke mesh 229 is horizontally disposed in the body 202 below the active far edge electrode 119 and electrically coupled to the active far edge electrode 119. One or more conductive vertical jumpers 290 extend from electrically conductive contact with an edge electrode conductor 229 within the body 202 of the electrostatic chuck 152 to electrically conductive contact with the lowermost surface of the active far edge electrode 119. The edge electrode conductor is connected, through the body of the electrostatic chuck 152, to a bias power supply, which can be the same, or a different, power supply than that used to impose an AC bias on the chucking electrodes. For example, the bias power supply 117 can provide AC (such as RF) energy through the edge electrode conductor 229 and through the vertical jumpers 290 to the active far edge electrode 119. A variable capacitor 217 may be disposed between the bias power supply 117 and the active far edge electrode 119.

In one example hereof, edge electrode is configured as a spoke mesh 300 as shown in FIG. 6A. Here, the spoke mesh 300 is configured from the woven mat or unitary mesh sheet 333 having the same or a similar wire size and relative weave configuration as that of the individual annular rings of the active far edge electrode 119 of FIGS. 2A and 2B. Here the spoke mesh 300 is cut or stamped from the unitary mesh sheet 333 into a wheel shape having at least two, as shown in FIG. 6A six, sections or spokes 302 radiating outwards from a center pad portion 301 which will be located near the circumferential center of the body 202, to an outer ring portion 303 here extending a continuous annular ring. In another example, the spoke mesh 300 has greater that six spokes radiating outwards from the pad portion at the center region of the body 202. The pad portion 301 of the spoke mesh 300 is connected through a conductive post in the body extending therefrom and outwardly of the body 202 to be electrically connected to a power supply.

Where the conductive jumpers 290 are used to connect the active far edge electrode 119 to the bias power supply, the annular ring portion 303 of the spoke mesh 229 is disposed inwardly of the body 202 of the electrostatic chuck 152 from the facing surface of the active far edge electrode 119 by a distance of between about 2 mm to about 6 mm, such as about 5 mm from the active far edge electrode 119, and the conductive jumpers 290 are in electrical contact therebetween. The spoke mesh 229 may be spaced about 2 mm to about 3 mm from the outer circumferential surface 255 of the electrostatic chuck 152. For example, the distance 297 of the spoke mesh 229 from the outer circumferential surface 255 may be about 2.5 mm.

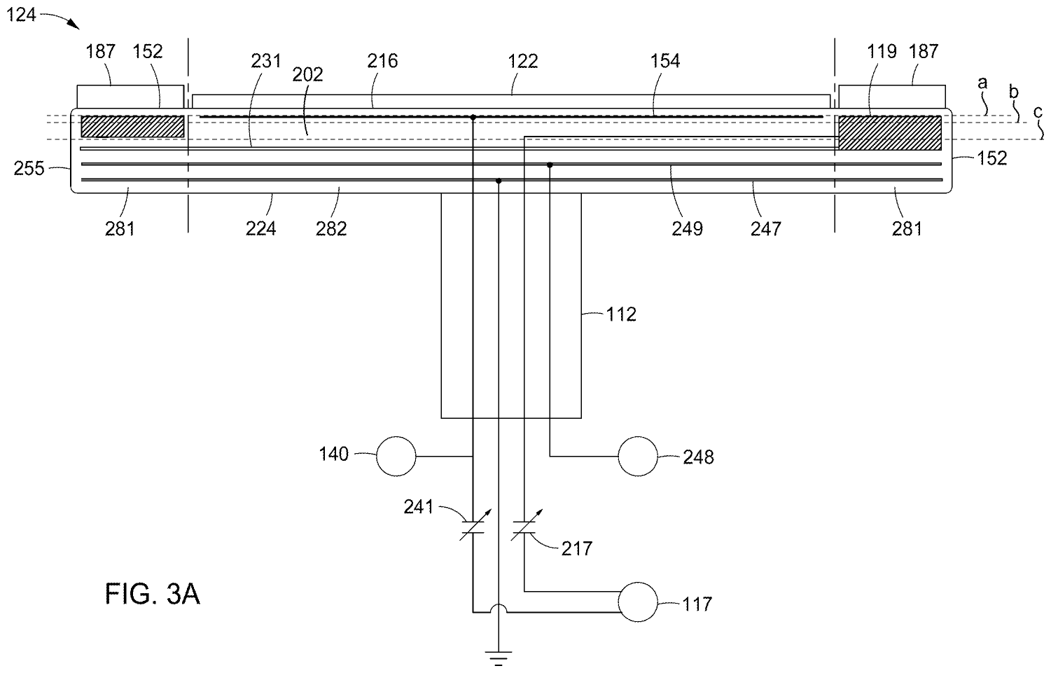

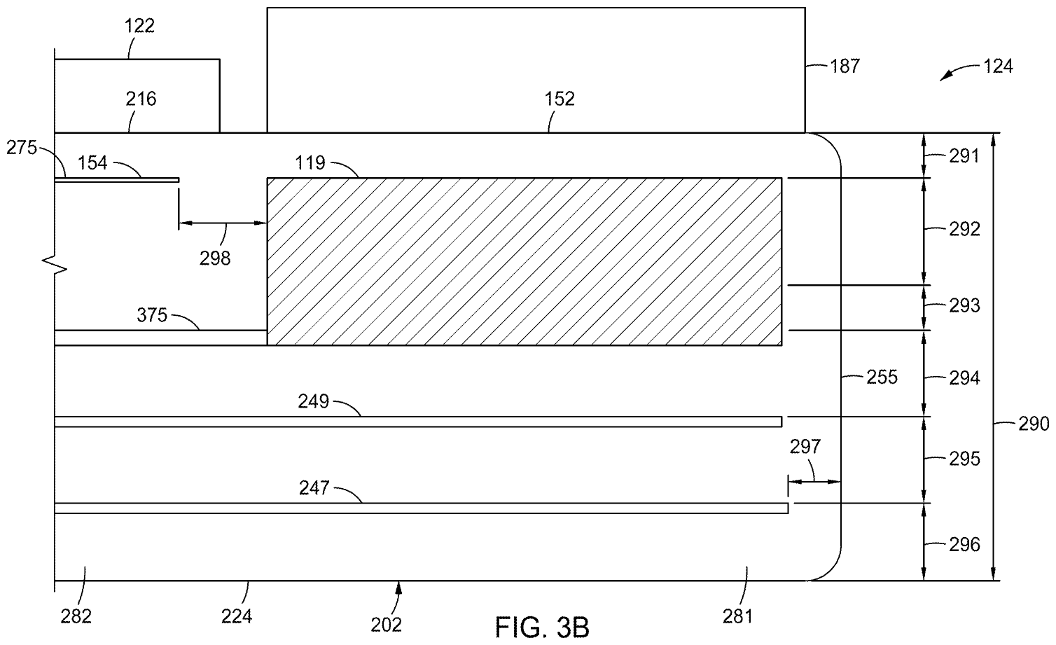

In another aspect hereof, as shown in FIGS. 3A and 3B, the active far edge electrode facing surface 375 of the annular ring portion 303 of the spoke mesh 300 is in direct contact with the surface of the active far edge electrode 300 facing away from the first side 216 of the body 202. This eliminates the need for a conductive jumper 290 leading to more reliable manufacture of the electrostatic chuck 152.

The individual rings of the active far edge electrode 119 to one another, and the active far edge electrode facing surface of the annular ring portion 303 of the spoke mesh 300 to the facing surface of the active far edge electrode are connected during sintering.

The body 202 of the electrostatic chuck 152 additionally has the floating mesh 231 embedded horizontally in the body 202 and disposed below the spoke mesh 229. The floating mesh 231 is not electrically coupled to the system ground or to any powered sources. In one example, the floating mesh 231 is unattached to a ground or other electric circuit. The floating mesh 231 helps filters out damaging RF signals from entering a non-RF environment. The floating mesh 231 is disposed between the RF hot sources, such as the spoke mesh 229, active far edge electrode 119, and chucking electrodes 154, and the non-RF hot features, such as the one or more heating elements 249 and ground mesh 247. The floating mesh 231 minimizes the RF signal from the RF hot sources from coupling to the one or more heating elements 249 or ground mesh 247.

The floating mesh 231 is disposed a distance 293 of between about 0.5 mm and about 2.0 mm below the spoke mesh 300. For example, the distance 293 of the floating mesh 231 below the spoke mesh 300 is about 1.0 mm. The floating mesh 231 may also be spaced about 2 mm to about 3 mm from the outer circumferential surface 255. For example, the distance 297 of the floating mesh 231 from the outer diameter of the outer circumferential surface 255 may be about 2.5 mm.

The one or more heating elements 249 are embedded in the body 202 below the spoke mesh 229. The heating elements 249 may be disposed a distance 294 of between about 4 mm and about 6 mm below the Floating mesh 231, such as about 5 mm below the Floating mesh 231. The heating elements 249 extend horizontally within the body 202 to between about 1.5 mm to about 3 mm from the outer diameter 255 of the outer circumferential surface 255 of the body 202. In one example, the distance 297 the heating elements 249 extend horizontally within the body 202 is about 2.5 mm from the outer diameter of the outer circumferential surface 255 of the body 202.

The heating elements 249 may be arranged in one or more zones to control a temperature of the electrostatic chuck 152. For example, the heating elements 249 may be arranged in one, two or four zones for supplying a temperature to the substrate 122. The heating elements 249 are coupled to a power source 248, e.g., an AC power source, to power the heating elements 249. The one or more heating elements 249 are configured to supply a temperature to the substrate of about 200 degrees Celsius to about 700 degrees Celsius. For example, the electrostatic chuck 152 is configured to operate at temperatures exceeding 600 degrees Celsius, such as about 650 degrees Celsius.

The ground mesh 247 is embedded in the body 202 below the heating elements 249. The ground mesh 247 is coupled to the system ground. The ground mesh 247 provides a conductive path for energy in the electrostatic chuck 152, such as that from the plasma, to be directed at the system ground and prevent arcing between the electrostatic chuck 152 and the sidewalls of the processing chamber 100.

The ground mesh 247 may be disposed a distance 295 of between about 3 mm and about 5 mm below the heating elements 249, such as about 4 mm below the heating elements 249. The distance 297 the ground mesh 247 extends horizontally within the body 202 is between about 1.5 mm to about 3 mm from the outer diameter of the outer circumferential surface 255 of the body 202. In one example, the ground mesh 247 extends horizontally within the body 202 to about 2.5 mm from the outer diameter of the outer circumferential surface 255 of the body 202. Additionally, the ground mesh 247 may be disposed a distance 296 of between about 1.5 mm and about 3.5 mm above the second side 224, such as about 2.5 mm above the second side 224. This arrangement places the ground mesh 247 as the closest feature in the body 202 to the second side 224, i.e., bottom surface of the ESC 152.

The embedded ground mesh 247 prevents RF coupling to the chamber bottom as well as plasma light-up in any gaps between the ESC and a ground shield found on conventional electrostatic chucks. The plasma light-up leads to undesired chemical deposition around the heater. The ground mesh 247 additionally helps reduce the depth and hence the internal volume of the processing chamber 100. This reduced volume helps to reduce the purge time required during a PEALD process.

In one example, the substrate 122 is electrostatically chucked onto the electrostatic chuck 152 using a DC power supply, and the temperature of the electrostatic chuck 152 is maintained at desired process temperatures using heater controllers while a thermocouple (also going through the shaft) provides feedback loop control, while RF biasing can be provided using bias power supply 117 as and when required for PEALD, PECVD, and etch/treatment steps.

Advantageously, the electrostatic chuck 152 as arranged can operate at temperatures up to 700 degrees C. along with the RF biasing capability to produce a denser plasma at the edges of the wafer. Additionally, the ground mesh 247 is embedded within the body 202 of the electrostatic chuck 152 to prevent RF coupling with the processing chamber 100. The low frequency pulsing between 0.2 Hz and 20 Hz for the bias power supply 117 provides RF biasing which enhances deposited film density on the substrate for in-situ treatment and/or etch.

Advantageously, the electrostatic chuck 152 can be used for both the PECVD/PEALD deposition and in-situ etch/treatment process while having superior wafer edge coverage using the active far edge electrode 119. The electrostatic chuck 152 also has a reduced footprint due to the embedded ground electrode that helps prevent plasma light up, i.e., arcing, in the gaps as seen in previous approaches to conventional grounding of electrostatic chucks.

To manufacture the electrostatic chuck 152 of FIGS. 3A and B, the stack of the chucking electrodes 154, other electrodes, the unitary spoke mesh 300 and the stack of annular rings providing the active far edge electrode 119 with a brazing compound therebetween, and the heater are layered within a body mold with ceramic powder therebetween. The mold is than filled with additional ceramic powder and fused into a unitary body in a heating apparatus with the stack of electrodes embedded within. For example, ceramic powder for the portion of the body forming the substrate support and edge ring regions thereof is first placed into a mold, and then the chucking electrodes and the stack of annular rings for the active far edge electrode 119 are placed over that powder. Additional powder is supplied, and additional electrodes such as the spoke mesh for providing the power to the active far edge electrode is located thereover. This sequence is repeated until all of the electrodes and the ceramic power to manufacture the body are present in the mold. Additionally, a conductive plug is preferably electrically and physically connected to each of the electrodes when placed into the mold, to allow for tolerance when drilling holes through the non-substrate support side of the body after the ceramic is fired to fuse it together and form the body 202 of the electrostatic chuck assembly 150. This ceramic powder with embedded electrodes is then heated to the ceramic fusing temperature to form a single ceramic piece comprising the body with the electrodes embedded therein.

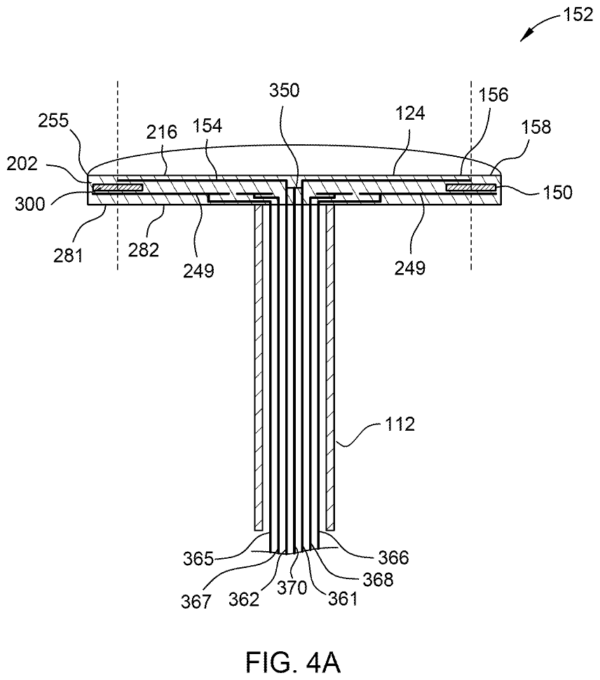

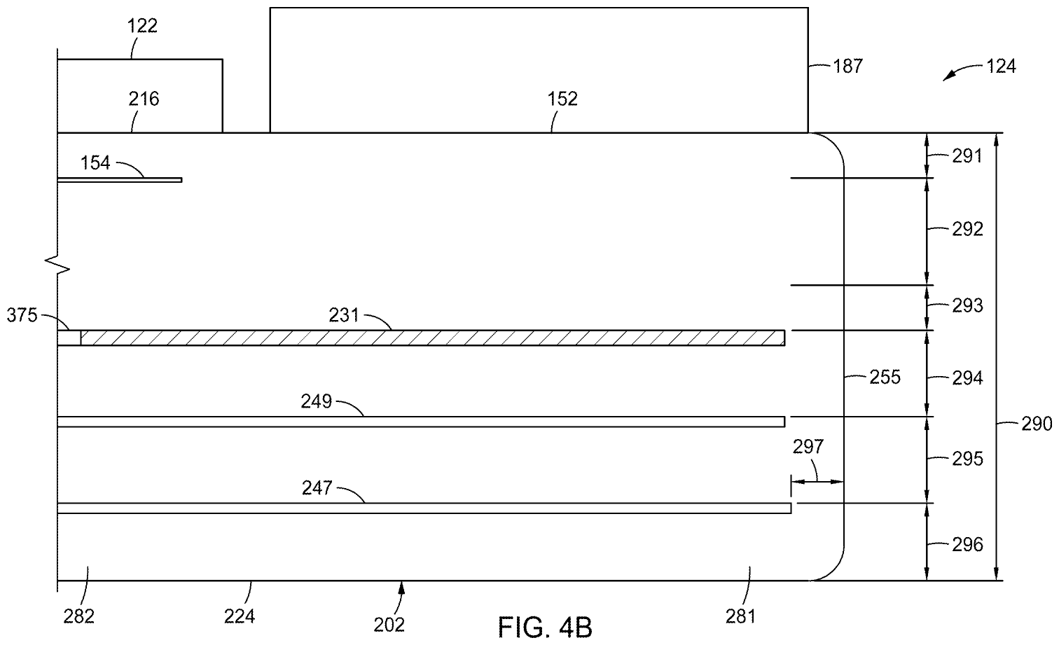

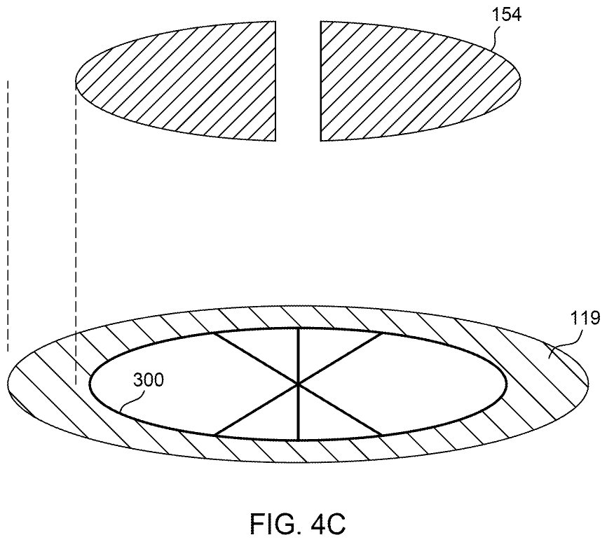

After firing and cooling, the ceramic body 202 is then drilled using a drill to form holes from the underside of the body to the conductive plugs connected to a first electrostatic chuck electrode, a second electrostatic chuck electrode, a first heater, a second heater, and the spoke mesh. Then individual studs or wires can be connected to the heater and the non-floating electrodes through brazing to the plugs. For example, the studs or wires, and the body 202, are held in relative positions to one another using appropriate fixturing and placed into a furnace where they are heated to above the solidus or melting temperature of the brazing material, to allow each of the wires to become physically and electrically connected to their respective component through the conductive plug. The brazing compound will bond to the mesh and the rod, and then the assembly is allowed to cool and the fixturing is removed. The hollow support shaft may be similarly connected during this brazing process using appropriate brazing material between connecting end of the hollow shaft 112 and the underside of the body. Alternatively the hollow support shaft may be diffusion bonded to the plate prior to brazing of the rods. In an alternative embodiment seen in FIGS. 4A and 4B, a schematic partial side view of the substrate support 124 is provided. The electrostatic chuck 152 is here of the same general construct as that described with respect to FIGS. 1 to 3B hereof, except the connection of the AC power supply to the active far edge electrode is different. Here, a floating passive far edge electrode 119a is employed, and power is supplied thereto via capacitive coupling with another electrode structure within the body 202 of electrostatic chuck. Thus, the conductive jumpers 290, or the spoke mesh being in direct electrical connection with the active far edge electrode is not present.

The one or more chucking electrodes 154 are embedded in the inner portion 282 of the body 202 immediately adjacent to the first side 216. The chucking electrodes 154, when energized, electrostatically chuck the substrate 122 to the first side 216 of the electrostatic chuck 152. The one or more chucking electrodes 154 may be monopolar or bipolar. In some examples, the electrostatic chuck 152 provides Coulombic chucking. In some examples, the electrostatic chuck 152 provides Johnsen-Rahbek chucking.

Embedded within the body 202 and below (from the first side 216 of the body 202) the chucking electrode 154 is configured of one or more annular rings cut or stamped from the unitary mesh sheet 333 to form the passive far edge electrode 119a. The inner radius and thus the inner circumferential portion of the passive far edge electrode 119a here extends inwardly of the substrate receiving region 156 of the body 202, and radially outwardly thereof to extend under the outer peripheral portion 158 of the body 202. Thus, a portion of the chucking electrodes 154 extend between a radially inner portion of the passive far edge electrode 119a and the upper surface 216 of the body.

In the embodiment of FIGS. 4A and 4B, the outer edges of the D-shaped chucking electrodes 154 generally lie along a radius from the center point of the chuck body 202, and the active far edge electrode 119 has an inner and outer radius, both extending and centered about the same center point of the chuck body 202. The passive far edge electrode 119a can thus be capacitively coupled to the unitary chucking electrodes, to pass the AC bias power from the chucking electrodes 154 into the passive far edge electrode 119a. The outer radius of the chucking electrode(s) referenced from the center point of the body 202 is larger than the inner radius of the passive far edge electrode 119a referenced from the center point. The inner radius of the passive far edge electrode 119a extends inwardly of the outer radius of the chucking electrode(s), and under the substrate receiving region 156 of the body. Thus the passive far edge electrode 119a inner radius overlaps with the outer radius of the chucking electrodes 154, and a portion of the chucking electrodes 154 adjacent their outer circumferences extend between the inner radius of the annular ring portion of the passive far edge electrode 119a Here, where more than one chucking electrode 154 is provided, the passive far edge electrode 119a can be provided in arcuate segments electrically isolated from one another in the circumferential direction, such that each segment underlies only of the chucking electrodes to be capacitively coupled thereto.

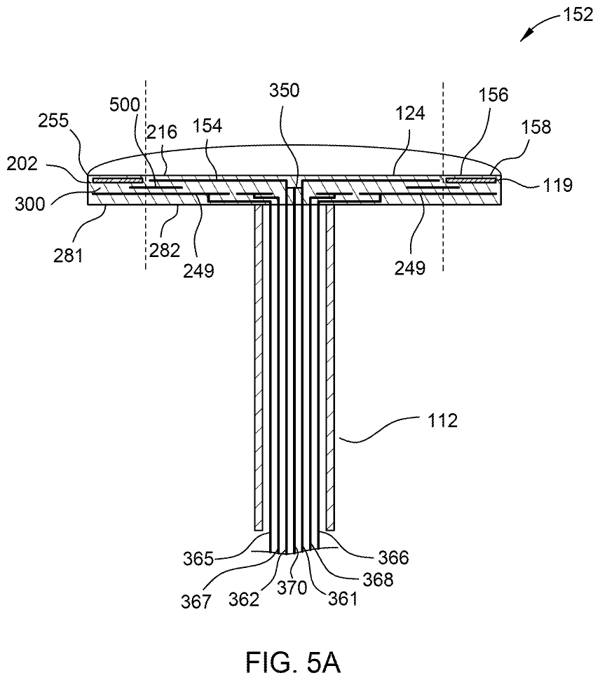

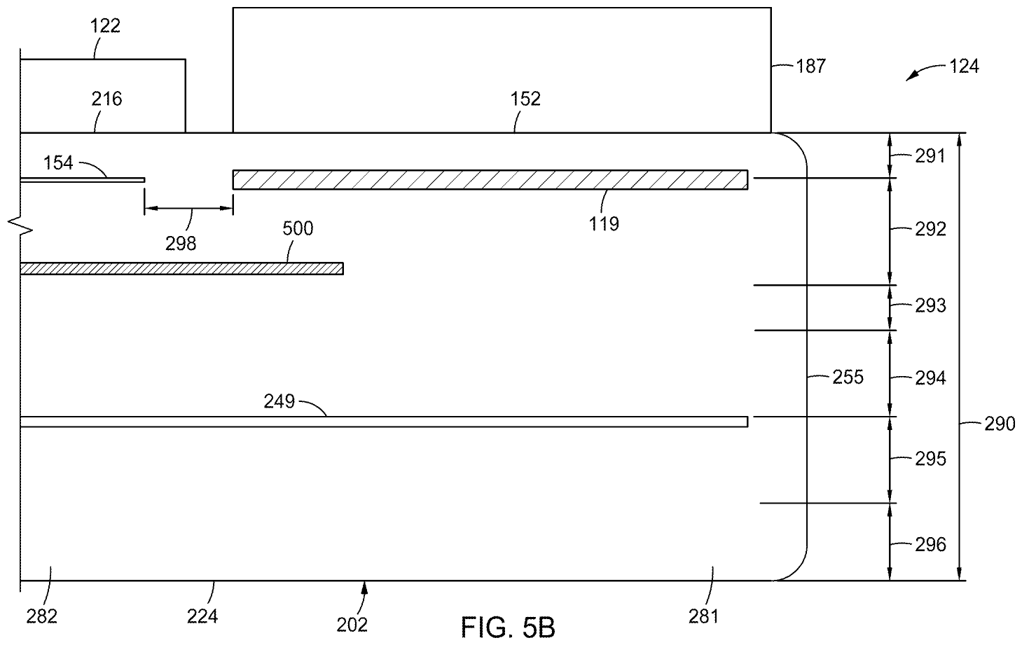

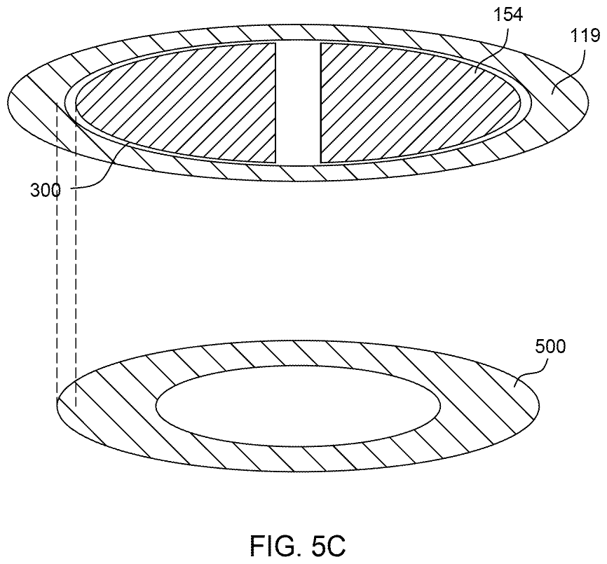

In an additional embodiment, as shown in FIGS. 5A and 5B, the passive far edge electrode 119a body is again not directly coupled to the power supply, but here, the first side 216 facing surface thereof extends generally in plane a, the same plane as that of the first side 216 facing surface of the chucking electrodes 154. To provide capacitive coupling thereof to another actively powered electrode, for example to the chucking electrode(s) 154, a passive jumper electrode 500 is employed. Here, the passive jumper electrode 500 is configured as an annular ring, for example cut or die cut from the unitary mesh sheet 333 having an inner radius and an outer radius. The outer circumferential portion of the electrode(s) 154 extends between the radially inner circumferential portion of the passive jumper electrode 500 and the first surface 216 of the body, and the radially inner circumferential portion of the passive far edge electrode 119a extends between the radially outer circumferential portion of the passive jumper electrode 500 and the first surface 216 of the body 202. Thus, AC power supplied to the chucking electrodes is capacitively coupled to the passive jumper electrode 500, and then this power is capacitively coupled to the passive far edge electrode 119a. Again, where more than one chucking electrode 154 is provided, an equal number of arcuate segments of the passive jumper electrode 500, each underlying a single one of the chucking electrodes 154 is provided, likewise, an equal number of arcuate segments of the passive far edge electrode 119a are provided, each overlying only one of the segments of the passive jumper electrode 500.

While the foregoing is directed to embodiments of the present disclosure, other and further embodiments of the disclosure may be devised without departing from the basic scope thereof, and the scope thereof is determined by the claims that follow.

What is claimed is:

1. A substrate support for use in a substrate processing chamber, the substrate support comprising:
a ceramic electrostatic chuck having a body, the body having an outer diameter, a first side configured to support a substrate and a second side opposite the first side, and a thickness between the first side and the second side, wherein the body comprises;
at least one chucking electrode having a radially outer surface;
a far edge electrode disposed adjacent to the chucking electrode and extending radially outwardly of the at least one chucking electrode; wherein
the far edge electrode has a thickness in the thickness direction of the body which is greater than the thickness of the at least one chucking electrode in the thickness direction of the body.

2. The substrate support of claim 1, further comprising the far edge electrode connected to one or more electrical jumper connections extending in the thickness direction of the body.

3. The substrate support of claim 2, wherein the body first side facing surface is disposed inwardly of the body of from the first surface as it the body first surface facing side of the at least one chucking electrode.

4. The substrate support of claim 1, wherein the body second side facing surface of the far edge electrode is in contact with a mesh electrode extending parallel to the first side of the body, and the mesh electrode is connected to a conductive stud extending outwardly from the second side of the body.

5. The substrate support of claim 1, wherein the far edge electrode is configured to operate independently of the chucking electrode.

6. The substrate support of claim 5, wherein the far edge electrode is configured to operate from the power source coupled to the chucking electrode.

7. A substrate support, comprising:
a ceramic body having a first surface,
at least one heater,
at least one chucking electrode having an outer circumferential surface, and
a first annular member having a first inner circumferential surface and a first outer circumferential portion, a portion of the outer circumferential surface of the chucking electrode extending between the first surface of the ceramic body and the first inner circumferential portion of the first annular member.

8. The substrate support of claim 7, further comprising a second annular member having a second inner circumferential portion, wherein the second inner circumferential portion extends between the first surface and the first outer circumferential surface.

9. The substrate support of claim 8, wherein the first annular member is electrically floating within the ceramic body.

10. The substrate support of claim 8, wherein the depth of at least chucking electrode and the second annular member from the first surface is the same depth.

11. The substrate support of claim 7, wherein the ceramic body includes a substrate receiving portion and an extending portion extending radially outwardly of the substrate support portion.

12. The substrate support of claim 7, wherein the first annular electrode is comprised of conductive wire mesh.

13. The substrate support of claim 7 wherein the second annular electrode is an annular portion of conductive wire mesh.

14. The substrate support of claim 13, wherein the at least one chucking electrode comprises a wire mesh.

15. A method of manufacturing a substrate support comprising:
providing a ceramic body having a first surface configured to receive a substrate thereon;
providing an annular ring having a first surface facing side and a first thickness in the ceramic body;
providing a chucking electrode having a first surface facing side and a second thickness different than the first thickness in the ceramic body; and,
positioning the annular ring circumferentially around the chucking electrode.

16. The method of claim 15, further comprising providing an electrical connection from an external power supply to the annular ring.

17. The method of claim 16, wherein the electrical connect comprises a unitary conductive mesh including a central stub portion, an outer annular portion, and an interconnecting portion all conjured from a unitary sheet of conductive mesh.

18. The method of claim 17, further comprising providing a conductive jumper within the body and between the outer annular portion of the unitary conductive mesh and the annular ring.

19. The method of claim 17, further comprising brazing a conductive plug to the center stub portion of the unitary spoke mesh.

20. The method of claim 17, further comprising forming the chucking electrode so that the outer circumference of the chucking electrode ends radially inwardly of the outer circumference of the active edge electrode; and
the distance of the first surface facing side of the annular ring from the first surface of the body and the distance of the first surface facing side of the chucking electrode from the first surface of the body are the same distance
